(19) United States
(12) Patent Application Publication
(10) Pub. No.: US 2010/0198754 A1
(43) Pub. Date: Aug. 5, 2010

(54) METHOD OF PROVIDING MODULAR BATTERY PACKS FOR A HYBRID VEHICLE

(75) Inventors: Thomas A. Jones, Macomb, MI (US); Therese A. Tant, Royal Oak, MI (US); Wade W. Bryant, Grosse Pointe Farms, MI (US); John Thomas Guerin, Bloomfield, MI (US); Richard J. Lannen, Royal Oak, MI (US); Norman K. Bucknor, Troy, MI (US); Brandon Jeffrey Flood, Royal Oak, MI (US); Brian V. Castillo, Royal Oak, MI (US); William R. Philippi, Sterling Heights, MI (US); Eric M. Kern, Macomb, MI (US); Jan H. Aase, Oakland Township, MI (US)

Correspondence Address: Quinn Law Group, PLLC, 39555 Orchard Hill Place, Suite 520, Novi, MI, 48375, US

(73) Assignee: GM GLOBAL TECHNOLOGY OPERATIONS, INC., Detroit, MI (US)

(21) Appl. No.: 12/637,821

(22) Filed: Dec. 15, 2009

Related U.S. Application Data
(60) Provisional application No. 61/148,649, filed on Jan. 30, 2009.

(51) Int. Cl. G06Q 90/00; H05K 13/00

(52) U.S. Cl. 705/500; 29/592.1

(57) ABSTRACT

A method of offering or providing batteries for a hybrid or electric vehicle allows the customer to choose a vehicle electrical battery power rating that will match their expected driving range needs. Specifically, the method includes offering different modular battery packs for an electric or hybrid electric vehicle. Each of the different modular battery packs has a different number of interconnected batteries, a different energy level, and is configured to be operable for providing propulsion power to the vehicle. At least one of the different modular battery packs is installed on the hybrid or electric vehicle. The method may include recharging and/or recycling used battery back modules.

### CROSS-REFERENCE TO RELATED APPLICATIONS

This application claims the benefit of U.S. Provisional Patent Application No. 61/148,649, filed Jan. 30, 2009, which is hereby incorporated by reference in its entirety.

### TECHNICAL FIELD

The invention relates to a method of providing batteries for a hybrid vehicle.

### BACKGROUND OF THE INVENTION

Automotive vehicles are becoming more customizable in order to meet the values and priorities of customers. Additionally, customers generally desire flexibility to reconfigure or to access various features of a vehicle to meet their specific needs. Mass reduction and associated improved fuel efficiency remains a priority.

Hybrid electric vehicles utilize batteries to provide electric power for propelling the vehicle, either in an electric-only operating mode or in an electrically-variable operating mode in which electric power and engine power is used to propel the vehicle. The batteries may be recharged by controlling the motor/generator to operate as a generator while the vehicle is operating. Some hybrid vehicles have batteries that are configured to be recharged using an offboard power source, such as a typical household electric supply, and are referred to as plug-in hybrids.

### SUMMARY OF THE INVENTION

A method of offering or providing batteries for a hybrid or electric vehicle allows the customer to choose a vehicle electrical battery power rating that will match their driving range needs by purchasing battery pack modules. The method may include recharging and/or recycling used battery back modules.

Specifically, the method includes offering different modular battery packs for an electric or hybrid electric vehicle. Each of the different modular battery packs has a different number of interconnected batteries, a different energy level, and is configured to be operable for providing propulsion power to the vehicle. The method further includes installing at least one of the different modular battery packs offered on the electric or hybrid vehicle.

The above features and advantages and other features and advantages of the present invention are readily apparent from the following detailed description of the best modes for carrying out the invention when taken in connection with the accompanying drawings.

### BRIEF DESCRIPTION OF THE DRAWINGS

FIG. 1 is a flow diagram illustrating a method of offering modular battery packs; and

FIG. 2 is a schematic perspective illustration of a vehicle having modular battery packs provided under the method of FIG. 1.

### DESCRIPTION OF THE PREFERRED EMBODIMENTS

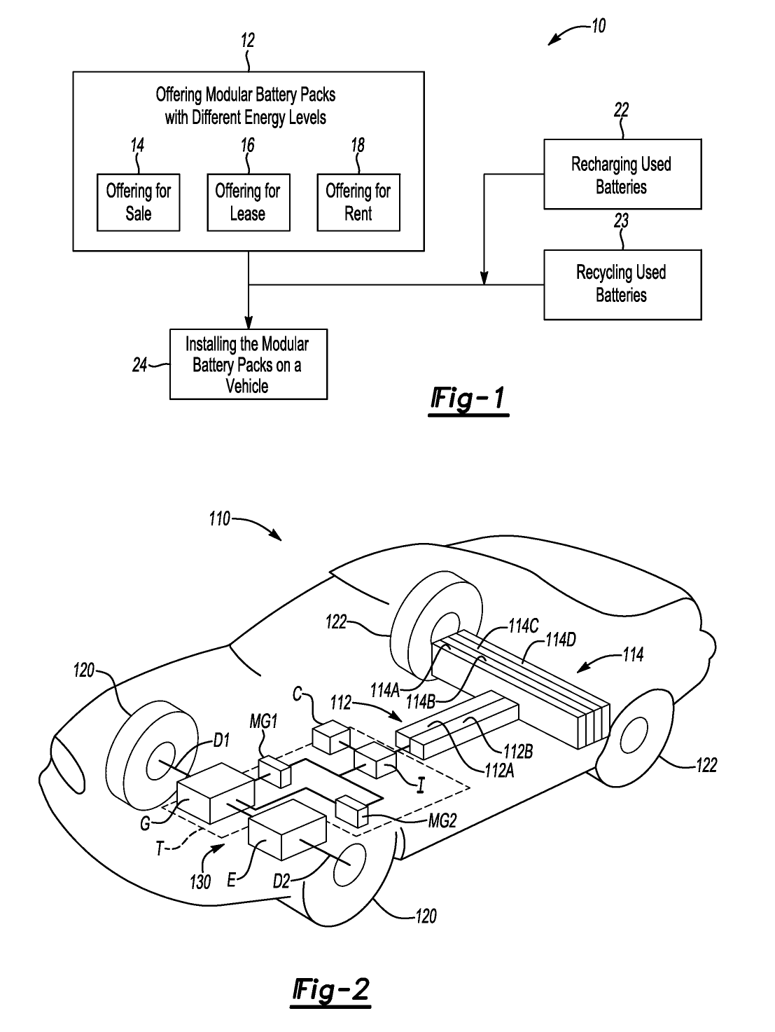

Referring to the drawings, wherein like reference numbers refer to like components throughout the several views, FIG. 1 shows a flow diagram illustrating a method 10 of offering or providing batteries for a hybrid or electric vehicle that allows the customer to choose a vehicle electrical battery power rating that will match their driving range needs. Some vehicle owners may plan to use their vehicles mainly or exclusively for relatively short trips, requiring a relatively low amount of electric power. The method 10 enables such customers to purchase one or only a few battery packs, thereby satisfying their driving needs but avoiding the extra weight and associated decrease in fuel economy of unnecessary battery packs. Other vehicle owners may plan to use their vehicles for long trips or for routes which will require the vehicle 110 to utilize electric power frequently. In those cases, modular battery pack combinations with a relatively high power rating may be selected.

The method 10 begins with step 12, offering modular battery packs with different energy levels. FIG. 2 shows a vehicle 110 that utilizes electric battery power for propulsion of front wheels 120, although the invention is not limited to a front-wheel drive vehicle, and may equally apply to a vehicle that utilizes electric power for propulsion of rear wheels 122. The vehicle 110 is a hybrid vehicle that has a powertrain 130 providing propulsion power to driveshafts D1, D2 of wheels 120 from both electric power and a power plant such as an internal combustion engine E. The engine E is interconnected with electro-mechanical transmission T. The transmission T includes several components bounded by a dashed line representing transmission T. The transmission T includes a gearing arrangement G to which two motor/generators MG1, MG2 are connected. A controller C controls the motor/generators MG1, MG2 to function as motors or as generators depending on vehicle operating conditions. When either MG1 or MG2 is functioning as a motor, electrical power is provided from the battery packs 112, 114 through an inverter I. When either MG1 or MG2 is functioning as a generator, kinetic energy is transformed into electrical energy to be stored in the battery packs 112, 114. Any type of electromechanical transmission may be used within the scope of the invention.

The vehicle 110 is shown with two different modular battery packs 112, 114. Modular battery pack 112 includes two interconnected batteries 112A, 112B. Modular battery pack 114 includes four interconnected batteries 114A, 114B, 114C, and 114D. Thus, the purchaser of vehicle 110 has chosen two different battery pack modules 112, 114. Under the method 10, the purchaser would also have the option of buying just one of the battery pack modules 112, 114, and the option of choosing a different number of batteries for the modules (e.g., either or both of the batteries 112A, 112B, and one, two, three, four, or more of the batteries 114A, 114B, 114C, 114D). The batteries 112A, 112B are configured to be interconnected with one another, as are batteries 114A, 114B, 114C and 114D. The battery pack modules 112, 114 are configured to be electrically interconnected with one another, or to be directly connected to the inverter I. In this embodiment, battery 112A of battery pack module 112 is electrically connected with the inverter I. Battery 112B is electrically connected with battery 112A, and battery 114A is electrically connected with both batteries 112A, 112B. Battery 114B is electrically connected with battery 114A and battery 114C. Battery 114D is electrically connected with battery 114C. Within the scope of the claimed invention, each battery pack offered and installed may include only one battery, or multiple batteries. The battery packs 112 and 114 shown with two and four batteries, respectively, are representative only.

Assuming that each battery 112A, 112B, 114A, 114B, 114C, and 114D has an electrical power rating for a typical twenty mile driving range at a given speed then battery pack modules 112, 114 provide a 120 mile driving range. The actual range values achieved would vary with the specific vehicle's mass. As used herein, the “energy level” or “electrical power rating” of a battery is the energy in watt-hours (Wh) that is deliverable by the battery. The energy in watt-hours may be stated as the expected driving range of the battery on a vehicle with a predetermined mass driven according to a predetermined duty cycle. If the customer requires only a twenty mile driving range before needing to recharge the battery pack module, they would purchase just a single battery 114A. If the customer requires a forty mile range, then they would buy a battery pack module that contains two of the batteries 114A, 114B. A desired driving range of sixty miles would lead to the purchase of a battery pack module with three of the batteries 114A, 114B, 114C, and so on. By allowing need-specific customization of battery power, overall vehicle cost and mass is reduced, and energy efficiency is improved.

Under the method 10, offering 12 of the modular battery packs may be further customized to include offering for sale 14, offering for lease 16, and offering for rent 18. Thus the transaction may be tailored to the expected length of time the customer will be using the modular battery packs. For example, if an extended road trip is planned, a customer may choose to increase available electric energy and driving range by renting a larger battery pack module or combination of modules for the duration of the trip. Alternatively, if a customer does not expect to use the vehicle for an amount of time that would warrant purchasing battery pack modules, or has certain energy-level driving needs for only a short period of time, the customer may choose to lease battery packs that are offered for lease under step 16. If a customer plans to use the vehicle for purposes with known energy needs for an extended period of time, such as a specific commute to work, he may choose to purchase one or more modular battery packs offered under step 12.

Before installing modular battery packs in the vehicle 110 under step 24, the manufacturer or other entity offering the modular battery packs 112, 114 may recharge used batteries under step 22 in order to configure the desired battery packs. For example, when a rented modular battery pack is returned, the batteries of the module may be recharged and used in the same module or reconfigured as part of different modules. Additionally, recycled used batteries may be reclaimed and recharged under step 23. In step 24, after the desired battery pack module or modules are configured for the customer, they are installed in step 24. The selected battery packs may be installed in any known manner, in a predetermined packaging space on the vehicle 110, such as in the cargo storage area, supported by the vehicle floor or frame.

While the best modes for carrying out the invention have been described in detail, those familiar with the art to which this invention relates will recognize various alternative designs and embodiments for practicing the invention within the scope of the appended claims.

1. A method comprising:
offering different modular battery packs for an electric or hybrid electric vehicle; wherein each of the different modular battery packs has a different number of interconnected batteries, a different energy level, and is configured to be operable for providing propulsion power to the vehicle; and
installing at least one of the offered modular battery packs on the electric or hybrid vehicle.

2. The method of claim 1, wherein each of the interconnected batteries of the modular battery packs is substantially the same energy level.

3. The method of claim 2, wherein each modular battery pack is operable for providing a total energy level substantially equal to a sum of the energy levels of the different interconnected batteries of the modular battery pack.

4. The method of claim 1, wherein the offering includes offering for sale.

5. The method of claim 1, wherein the offering includes offering for lease.

6. The method of claim 1, wherein the offering includes offering for rent.

7. The method of claim 1, wherein at least some of the interconnected batteries of at least one of the different modular battery packs is recycled.

8. The method of claim 1, wherein at least one of the interconnected batteries of at least one of the different modular battery packs is recharged.

9. A method comprising:
installing at least one modular battery back on an electric or hybrid vehicle; wherein the at least one modular battery back is selected from a group of different modular battery packs; wherein each of the different modular battery packs has a different number of interconnected batteries, a different energy level corresponding to the number of interconnected batteries, and is configured to be operable for providing propulsion power to the vehicle; and wherein the at least one installed modular battery back is sold, leased, and rented.

10. The method of claim 9, wherein at least some of the interconnected batteries are recharged batteries.

11. The method of claim 9, wherein at least some of the interconnected batteries are recycled batteries.

12. A method comprising:
offering different modular battery packs for an electric or hybrid electric vehicle; wherein each of the different modular battery packs has a different number of interconnected batteries, a different energy level, and is configured to be operable for providing propulsion power to the vehicle;
recharging at least one of the different modular battery packs;
recycling at least one other of the different modular battery packs;
installing at least some of the different modular battery packs offered on the electric or hybrid vehicle; and wherein the battery packs installed include either the at least one recharged modular battery pack or the at least one recycled modular battery pack.
